(19) United States
(12) Patent Application Publication
(10) Pub. No.: US 2005/0253630 A1
(43) Pub. Date: Nov. 17, 2005

(54) Dual-modulus prescaler using double edge triggered D-flip-flops

(76) Inventors: Hong-Yi Huang, Taipei City (TW); Sheng-Feng Ho, Taipei (TW); Hsuan-Yi Su, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/842,569

(22) Filed: May 11, 2004

(51) Int. Cl. H03K 21/00

(52) U.S. Cl. 327/115

(57) ABSTRACT

The present invention provides one dual-modulus prescaler using double edge triggered D-flip-flops. The dual-modulus prescaler comprises one double edge triggered synchronous block, one asynchronous block, and one combination logic block. The double edge triggered synchronous block is used to receive an input signal and a divisor selection signal from the combination logic block, and output a synchronous block output signal to the asynchronous block. The asynchronous block is used to receive the synchronous block output signal and output a plurality of signals to the combination logic block. One of the output signals of the asynchronous block is the output signal of the dual-modulus prescaler. The combination logic block is used to receive all the output signals of the asynchronous block and a modulus selection signal. Then, the combination logic block outputs the divisor selection signal and feeds it back to the double edge triggered synchronous block. The double edge triggered synchronous blockish composed of a plurality of D-flip-flops.

### BACKGROUND OF THE INVENTION

1. Field of the Invention

The present invention relates to a double edge triggered dual-modulus prescaler, and particularly to dual-modulus prescaler using double edge triggered D-flip-flops and reducing the ratio of the divisor.

2. Description of the Prior Art

In a microwave circuit design, it has been one of the challenges to design a Phase-Locked Loop (PLL) operating in the microwave frequency range. In the high frequency application, so far Gallium Arsenide (GaAs) is used to manufacture chips. But with the rapid advancing of the CMOS technology, designers use the technology to achieve the advanced circuit gradually. Besides, in the modern communication, taking portal phones for example, it is necessary to operate in the precise frequency and with durable batteries. Therefore the high frequency and low power design are very important.

FIG. 1 is a block diagram of a conventional Frequency Synthesizer including a phase frequency detector, a charge pump, a loop filter, a voltage controlled oscillator, a divider divided by 2, and a single edge triggered (SET) prescaler. The input reference frequency f_{ref} is 27.9 Mhz and the output frequency fᵥₒ is 1.8 Ghz. The divisor of the SET dual-modulus prescaler is 128 or 129 (128/129). In the circuit, the output frequency f_{vco} from the voltage-controlled oscillator is 3.6 Ghz, which becomes the input of the SET dual-modulus prescaler and the divider divided by 2. The final output frequency of the divider divided by 2 is 1.8 Ghz.

FIG. 2 is the block diagram of the SET dual-modulus prescaler 100 in FIG. 1. The SET dual-modulus prescaler includes an SET synchronous block 110, an asynchronous block 120, and a combinational logic block 130. The SET synchronous block receives an input signal Fᵢₙ and a feedback divisor selection signal Dₛₑₗ coming from the combinational logic block 130, then outputs a signal F_{syn} to the asynchronous block 120. And then the asynchronous block produces a plurality of output signals and sends the output signals to the combinational logic block 130. One of the output signals is the output signal F_{fb} of the SET dual-modulus prescaler 100. The combinational logic block 130 receives output signals coming from the asynchronous block 120 and a modulus selection signal F_{mode}, then outputs a divisor selection signal Dₛₑₗ, and then feeds back the divisor selection signal Dₛₑₗ to SET synchronous block 110.

The SET synchronous block 110 and the asynchronous block are combined by a plurality of D-flip-flops (DFF). D-flip-flops can be differentiated as static and dynamic. Because of the shorter setup time of the dynamic D-flip-flops, the dynamic D-flip-flops can make a system operate in a higher speed. FIG. 3 is a block diagram of a SET D-flip-flops (SET-DFF). The input signal enters from the terminal D, timing signal enters from the terminal φ, output signal leaves from the terminal Q, and inverse signal of the terminal φ leaves from the terminal ˜Q. FIG. 4 is the practical circuit diagram of the dynamic SET-DFF. FIG. 5 is the timing diagram of the signal of the dynamic SET-DFF. In FIG. 5, at time t0, t1 and t2, the timing signal φ is positive triggered, and the output terminal Q is locked and outputs the same signal with the signal of the terminal D. But when the timing signal φ keeps at “0”, “1” or is negative triggered, the output signal of the terminal Q keeps the same.

FIG. 6 is a circuit diagram of the SET synchronous block 110. The purpose of this circuit is to produce a synchronous block output signal F_{syn}. The frequency of the F_{syn} is the original frequency of the input signal Fᵢₙ divided by 4 or 5. The divisor is selected by the modulus selection signal F_{mode} produced by the combinational logic block 130. When the F_{mode} is 0, the divisor is 4, and when the F_{mode} is 1, the divisor is 5. The purpose of the asynchronous block 120 is to produce an output signal F_{fb}. And the frequency of the F_{fb} is divided by 32. According to the above, the frequency of the F_{fb} is the frequency of input signal Fᵢₙ divided by 128 or 129.

Because high-speed operation needs high current input, the frequency synthesizer in FIG. 1 consumes lots of energy. Therefore besides increasing the operating frequency of the frequency synthesizer, it is also an urgent topic to be resolved about how to decrease the consumption of the energy when the frequency synthesizer works.

### SUMMARY OF THE INVENTION

The invention proposes a double edge triggered dual-modulus prescaler. The main purpose of the invention is to reduce the ratio of the divisor with the combination of a plurality of double edge triggered DFF. Another purpose of the invention is to decrease the energy consumption when the frequency synthesizer works by decreasing the ratio of the divisor of the frequency synthesizer.

According to the above, the invention provides a double edge triggered dual-modulus prescaler, comprising a double edge triggered synchronous block, an asynchronous block, and a combinational logic block. The double edge triggered synchronous block receives an input signal and a feedback divisor selection signal coming from the combinational logic block, then outputs a synchronous block output signal to the asynchronous block, and the asynchronous block produces a plurality of output signals to the combinational logic block. One of the output signals is the output signal of the whole double edge triggered dual-modulus prescaler. The combinational logic block receives a plurality of the output signals and a modulus selection signal coming from the asynchronous block, then outputs the divisor selection signal, and feeds the modulus selection signal back to the double edge triggered synchronous block. The double edge triggered synchronous block comprises a plurality of double edge triggered DFFs.

### DESCRIPTION OF THE PREFERRED EMBODIMENT

The above is a brief introduction of the invention. The following is the further description in detail with figures. The related figures and description about the invention in the following are not limited by the preferred embodiment. In contrast, they mean to cover the spirits of the invention and the entire alternative, modified and similar cases defined in the appended claims.

Referring to FIG. 7, it is a block diagram of a double edge triggered dual-modulus frequency synthesizer using the invention. The frequency synthesizer, comprised of the invention, the double edge triggered dual-modulus prescaler, comprises a phase frequency detector, a charge pump, a loop filter, a voltage controlled oscillator, and a double edge triggered (DET) dual-modulus prescaler. When the input reference frequency of the frequency synthesizer f_{ref} is 27.9 MHz and the expected output frequency f_{vco} is 1.8 MHz, it can be achieved by only changing the divisor of the DET dual-modulus prescaler to 64 or 64.5. Because the frequency synthesizer uses the design of the DET dual-modulus prescaler, the output frequency f_{vco} of the voltage-controlled oscillator is only half of the frequency of the frequency synthesizer of the prior art in FIG. 1. It can reduce the energy consumption of the voltage controlled oscillator and the frequency synthesizer.

In the following, the structure and the operating method of the DET dual-modulus prescaler of the invention are described in detail.

As shown in FIG. 8, it is the block diagram of the DET dual-modulus prescaler 200 provided by the invention, including a DET synchronous block 210, an asynchronous block 220, and a combinational logic block 230.

The DET synchronous block 210 receives an input signal Fᵢₙ and a feedback divisor selection signal Dₛₑₗ coming from the combinational logic block 230, then outputs a synchronous block output signal F_{syn} to the asynchronous block 220. The frequency of the output signal F_{syn} of the DET synchronous block is the frequency of the original input signal Fᵢₙ divided by 2 or 2.5. After receiving the F_{syn}, the asynchronous block 220 produces a plurality of output signals and sends the signals to the combinational logic block 230. One of the signals is the output signal F_{fb} of the whole DET dual-modulus prescaler 200. The frequency of output signal F_{syn} of the asynchronous block 220 is the frequency of the F_{syn} divided by 32. According to the above, the frequency of the output signal F_{fb} of the prescaler 200 is the frequency of Fᵢₙ divided by 64 or 64.5. The combinational logic block 230 receives a plurality of the output signals of the asynchronous block 220 and a modulus selection signal F_{mode}, then outputs the divisor selection signal Dₛₑₗ and feeds the Dₛₑₗ back to the DET synchronous block 210. Therefore the modulus selection signal F_{mode} can be used to select the relationship of the divisors between the output signal F_{syn} and the Fᵢₙ. When the modulus selection signal F_{mode} is “0”, the frequency of the output signal F_{syn} is the original input signal Fᵢₙ divided by 2. When the modulus selection signal F_{mode} is “1”, the frequency of the output signal F_{syn} is the original input signal Fᵢₙ divided by 2.5.

The DET synchronous block 210 comprises a plurality of DET D-flip-flops. FIG. 9 is the block diagram of a DET D-flip-flop. The input enters from terminal D. The timing signal enters from terminal φ. There is no inverse timing signal enters from terminal ˜φ. The output signal leaves from terminal Q. There is an inverse signal of terminal Q leaves from ˜Q. In FIG. 10, it shows the practical circuit diagram of the DET D-flip-flop, comprising two SET D-flip-flops as shown in FIG. 4 in parallel. FIG. 11 shows the timing diagram of the signal of the DET D-flip-flop. The DET D-flip-flop is locked and outputs the same signal as the signal of the terminal D not only when the timing signal is positive triggered but also negative triggered. As shown in FIG. 11, at time t0, t2 and t4, when the timing signal φ is positive triggered, the output terminal Q is locked and outputs the same signal “1” as the input terminal D. At time t1, t3 and t5, when the timing signal φ is negative triggered, the output terminal Q is locked and outputs the same signal “0” as the input terminal D. When the timing signal φ keeps at “0” or “1”, the output signal of the terminal Q keeps the same.

As described in the above, the DET synchronous block 210 of the invention comprises a plurality of DET D-flip-flops. FIG. 12 is one of the embodiments of the circuit structure of the DET synchronous block 210 of the invention. The synchronous block 210 includes three DET D-flip-flops (DFF1, DFF2, DFF3) and two NAND gates (G1, G2) to form a circuit with a division function by 2 or 2.5. When an input signal Fᵢₙ and its inverse signal ˜Fᵢₙ are sent to φ1-φ3 and ˜φ1-˜φ 3 of the DET-DFF1-DET-DFF3 respectively, DET-DFF1 outputs a synchronous block output signal F_{syn} from terminal Q1. In the meantime, signal F_{syn} is sent to terminal D2 of the DET-DFF2. Then the DET-DFF2 produces a pair of signals contrary to each other, output from terminal Q2 and ˜Q2. After the output signal of the terminal ˜Q2 of the DET-DFF2 and the divisor selection signal Dₛₑₗ pass through the NAND gate G2, a signal is produced and sent to the terminal D3 of the DET-DFF3. The signal produced from the terminal Q3 of the DET-DFF2 and the signal produced from the Q2 are fed together back to NAND gate G1, then a signal is produced and sent to the terminal D1 of the DET-DFF1.

Because the main purpose of the DET synchronous block 210 is to output the synchronous block output signal F_{syn} at the terminal Q1 of the DET-DFF1, the frequency of the F_{syn} is the frequency of the input signal Fᵢₙ divided by 2 or 2.5. The timing diagram of the signal of the synchronous divisor block 210 is shown as FIG. 13. When the modulus selection signal F_{mode} is “0”, the frequency of the output signal F_{syn} is the frequency of the original input signal Fᵢₙ divided by 2. When the modulus selection signal F_{mode} is “1”, the frequency of the output signal F_{syn} is the frequency of the original input signal Fᵢₙ divided by 2.5. For example, when the modulus selection signal F_{mode} is “0”, the output of the terminal Q3 of the DET-DFF3 keeps at “1”. The circuit works as a shift register, and the whole mode is 2×32=64. When the modulus selection signal F_{mode} is “1”, the output signals of the terminal Q2 and Q3 are fed back through NAND gate G1, and a signal is produced and kept at “1” within one and half periods and at “0” within one period.

Referring to FIG. 14, it is a DET asynchronous block 220 circuit structure of an embodiment of the invention. The DET asynchronous block 220 includes five SET D-flip-flops (SET-DFF1-SET-DFF5) to form a circuit with the division function by 32. When the synchronous block output signal F_{syn} coming from the DET synchronous 210 is sent to the terminal φ1 of the SET-DFF1, every output signal coming from the terminal ˜Q1-˜Q5 of each of the SET D-flip-flops is fed back to its input terminal D1-D5. An output signal Fₒᵤₜ₁ is produced at the terminal Q1 of the SET-DFF1, and sent to the terminal φ2 of the SET-DFF2. An output signal Fₒᵤₜ₂ is produced at the terminal Q2 of the SET-DFF2, and sent to the terminal φ3 of the SET-DFF3. An output signal Fₒᵤₜ₃ is produced at the terminal Q3 of the SET-DFF3, and sent to the terminal φ4 of the SET-DFF4. An output signal Fₒᵤₜ₄ is produced at the terminal Q4 of the SET-DFF4, and sent to the terminal φ5 of the SET-DFF5. Fₒᵤₜ₁-Fout4 are sent to combinational logic block 230, and an output signal F_{fb} is produced at terminal Q5 of the SET-DFF5.

The main purpose of the asynchronous block 220 is to divide the frequency of the output signal F_{syn} of the synchronous block 210 by 32, and produce an output signal F_{fb} at terminal Q5 of the DET-DFF5 to be fed back to the synchronous block 210. Because the synchronous block 210 is the circuit with the division function by 2 or 2.5 comprising three DET D-flip-flops, the purpose of the division by 64 or 64.5 can be achieved when a feedback signal F_{fb} is processed by the asynchronous block 220.

Referring to FIG. 15, it is a combinational logic block 230 circuit structure of an embodiment of the invention. The combinational logic block 230 includes a NOR date (G1), a NAND gate (G2), and an inverter (G3). The NOR gate receives the output signals Fₒᵤₜ₁ Fₒᵤₜ₄ and F_{fb}, and produces an output to the NAND gate. Then the NAND gate receives the output signals from the NOR gate and a modulus selection signal F_{mode} to produce an output to the inverter. At last, the inverter G3 receives the output from the NAND gate, and produces a divisor selection signal Dₛₑₗ. When the modulus selection signal F_{mode} is “1” and all of the outputs of the NOR gate are “0”, the divisor selection signal Dₛₑₗ is “1”. Then the divisor selection signal Dₛₑₗ is sent to the DET synchronous block 210, and the divisor 2.5 is chosen. The function of the divisor 2.5 can only last for one period, because all of the outputs of the asynchronous block 220 is going to be “1” at the next period. Therefore, the whole mode is 31×2+2.5=64.5.

According to the above, the invention has disclosed a DET dual-modulus prescaler 200 comprising a synchronous block 210, asynchronous block 220, and combinational logic block 230. The synchronous block 210 comprises three DET D-flip-flops with the division function by 2 or 2.5. The asynchronous block 220 comprises five SET D-flip-flops with the division by 32. The combinational logic block 230 can provide the divisor selection signal. Therefore the prescaler 200 has the function to divide an input by 64 or 64.5. But there are other different structures of the combinations of the DET and SET D-flip-flops to achieve the prescaler with the division function by 64 or 64.5 like the invention.

As shown in FIG. 16, it bases on another DET dual-modulus prescaler 300 circuit structure of an embodiment of the invention. The prescaler 300 includes a DET synchronous block 310, an asynchronous block 320, and a combinational logic block 330. In the following, only the differences of the similar function blocks between the FIG. 16 and FIG. 8 are going to be described. The block 310 comprises two DET D-flip-flops (DET-DFF1-DET-DFF2). The purpose of the block is to output a synchronous block signal F_{syn} at terminal Q1 of the DET-DFF1 with a frequency that is the frequency of the original input signal Fᵢₙ divided by 1 or 1.5. The asynchronous block 320 comprises six SET D-flip-flops (SET-DFF1-SET-DFF6), and produces 6 output signals Fₒᵤₜ₁-Fₒᵤₜ₆ and F_{fb} to combinational logic block 330. The purpose of the asynchronous block 320 is to produce an output signal F_{fb} with a frequency that is the frequency of the input synchronous block signal F_{syn} divided by 64. The frequency of the last output signal F_{fb} is the frequency of the original input signal Fᵢₙ divided by 64 or 64.5.

The timing diagram of the signal of the DET synchronous block 310 is shown as FIG. 17. When the modulus selection signal F_{mode} is “0”, the frequency of the output signal F_{syn} is the original input signal Fᵢₙ divided by 1. When the modulus selection signal F_{mode} is “1”, the frequency of the output signal F_{syn} is the original input signal Fᵢₙ divided by 1.5. When the modulus selection signal F_{mode} is “0”, the output at the terminal Q2 of the DET-DFF2 keeps at “1”. The circuit works as a shift register, and the mode is 1×64=64. When the modulus selection signal F_{mode} is “1”, the output signals of the terminal Q1 and Q2 are fed back through a NAND gate G1 and outputs a signal keeping at “1” within a period, and at “0” within half period. When the modulus selection signal F_{mode} is “1” and all of six the inputs of the NOR gate (G1) are “0”, the divisor selection signal Dₛₑₗ is “1”. When the divisor selection signal Dₛₑₗ is sent to DET synchronous block 310, the divisor is 1.5. The function of the divisor 1.5 can only last for one period, because all of the inputs of the asynchronous block 320 are going to be “1” at the next period. Therefore the mode is 63×1+1.5=64.5.

FIG. 18 shows a DET dual-modulus 400 circuit structure of another embodiment of the invention. It includes DET synchronous block 410, an asynchronous block 420, and a combinational logic block 430. The block 410 comprises five DET D-flip-flops (DET-DFF1-DET-DFF5). The purpose of the block 410 is to output a synchronous block signal F_{syn} at terminal Q2 of the DET-DFF2 with a frequency that is the frequency of the original input signal Fᵢₙ divided by 14 or 4.5. The asynchronous block 420 comprises four SET D-flip-flops (SET-DFF1-SET-DFF4), and produces 4 output signals Fₒᵤₜ₁-Fₒᵤₜ₄ and F_{fb} to combinational logic block 430. The purpose of the asynchronous block 420 is to produce an output signal F_{fb} with a frequency that is the frequency of the input synchronous block signal F_{syn} divided by 16. The frequency of the last output signal F_{fb} is the frequency of the original input signal Fᵢₙ divided by 64 or 64.5.

The timing diagram of the signal of the DET synchronous block 410 is shown as FIG. 19. When the modulus selection signal F_{mode} is “0”, the frequency of the output signal F_{syn} is the original input signal Fᵢₙ divided by 4. When the modulus selection signal F_{mode} is “1”, the frequency of the output signal F_{syn} is the original input signal Fᵢₙ divided by 4.5. When the modulus selection signal F_{mode} is “0”, the output at the terminal Q5 of the DET-DFF5 keeps at “1”. The circuit works as a shift register, and the mode is 4×16=64. When the modulus selection signal F_{mode} is “1”, the output signals of the terminal Q1 and Q2 are fed back through a NAND gate G1 and a signal keeping at “1” is outputted within 2.5 periods, and at “0” within 2 periods. When the modulus selection signal F_{mode} is “1” and all four inputs of the NOR gate (G1) are “0”, the divisor selection signal Dₛₑₗ is “1”. When the divisor selection signal Dₛₑₗ is sent to DET synchronous block 410, the divisor is 4.5. The function of the divisor 4.5 can only last for one period, because all of the inputs of the asynchronous block 420 are going to be “1” at the next period. Therefore the mode is 15×4+4.5=64.5.

When the output signal of the asynchronous block is only one. It is called Phase-locked loop. It is a special case of the frequency synthesizer.

The following is to make a comparison between the invention and the prior art of the dual-modulus prescaler about the output frequency, the number of the transistor, and power consumption. As shown in Table 1, when the supplied voltage is 2.5V, and the maximum operating frequency of the dual-modulus prescaler is 1.8 GHz, the power consumption of the prescaler is 5.312 mW, and the power consumption of the voltage-controlled oscillator is 2.184 mW. According to the table, the power consumption of the dual-modulus prescaler and the voltage-controlled oscillator of the invention of the invention is less than the prior art of the dual-modulus prescaler by 20%. When a frequency synthesizer uses the invention to operate, it can decrease the power consumption at high frequency operation. The invention can make the frequency synthesizer perform better, prolong the frequency synthesizer's life, and increase its reliability.

The invention has disclosed some structures that can form the 64/64.5 prescaler. But they are just the embodiments of the invention. They are not used to limit the application of the invention. Obviously, by changing the number of the DET D-flip-flops (to form the synchronous block) and SET D-flip-flops (to from asynchronous block), different prescalers of divisors can be made.

The above are only the embodiments of the invention. They are not used to limit the scope of the claims of the invention. The equivalent alteration or modification without departing from the disclosed spirits of the invention should be included in the scope of the following claims.

### BRIEF DESCRIPTION OF THE DRAWINGS

FIG. 1 is a block diagram of a prior art of a frequency synthesizer;

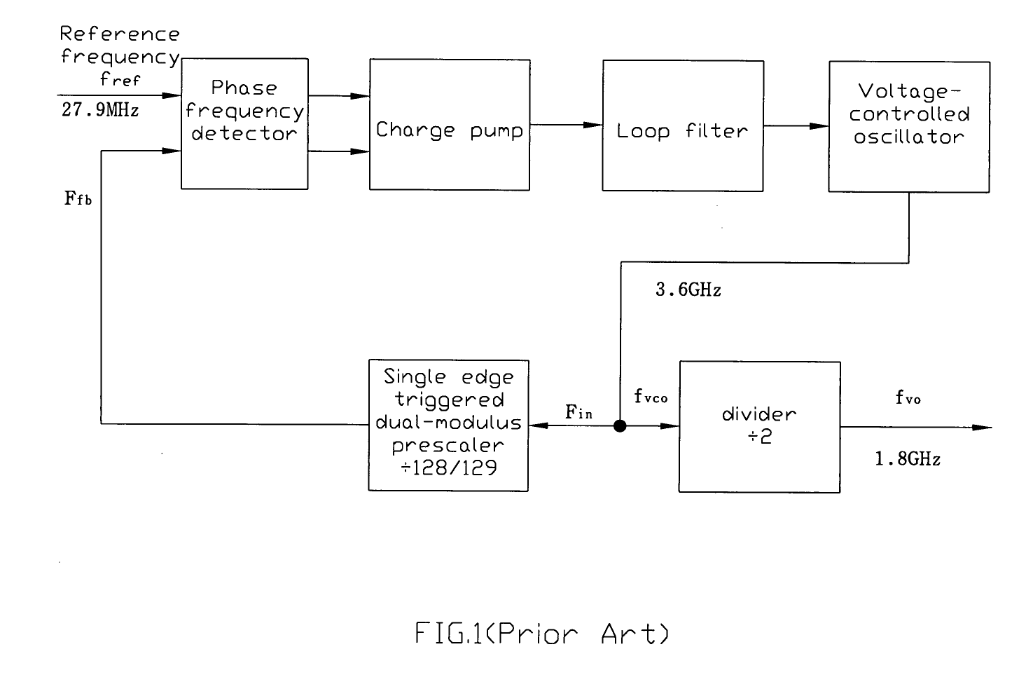

FIG. 2 is a block diagram of a prior art of a single edge triggered dual-modulus prescaler;

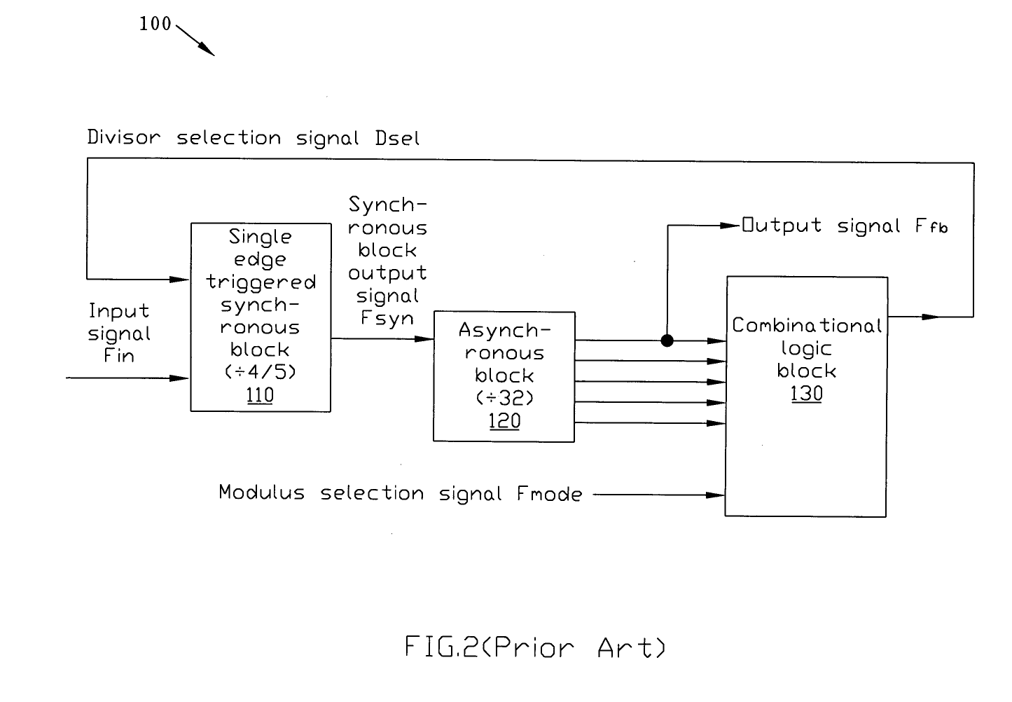

FIG. 3 is a diagram of a dynamic single edge triggered D-flip-flop;

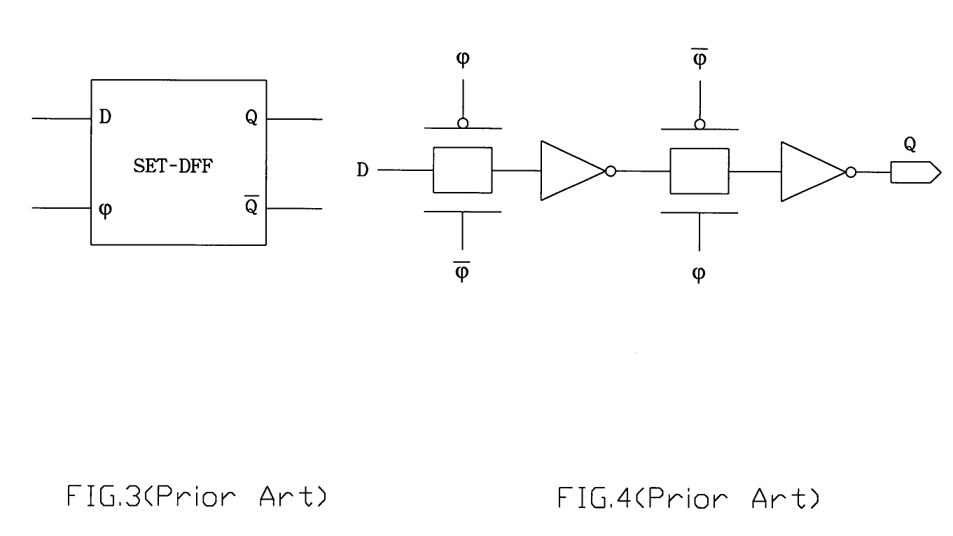

FIG. 4 is a practical circuit diagram of a dynamic single edge triggered D-flip-flop;

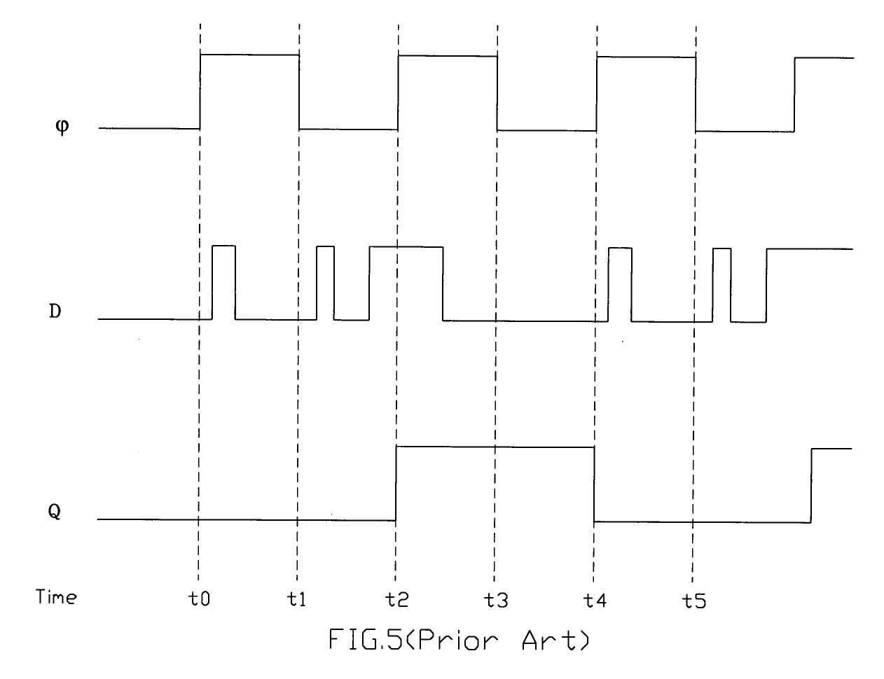

FIG. 5 is a timing diagram of a signal of a dynamic single edge triggered D-flip-flop;

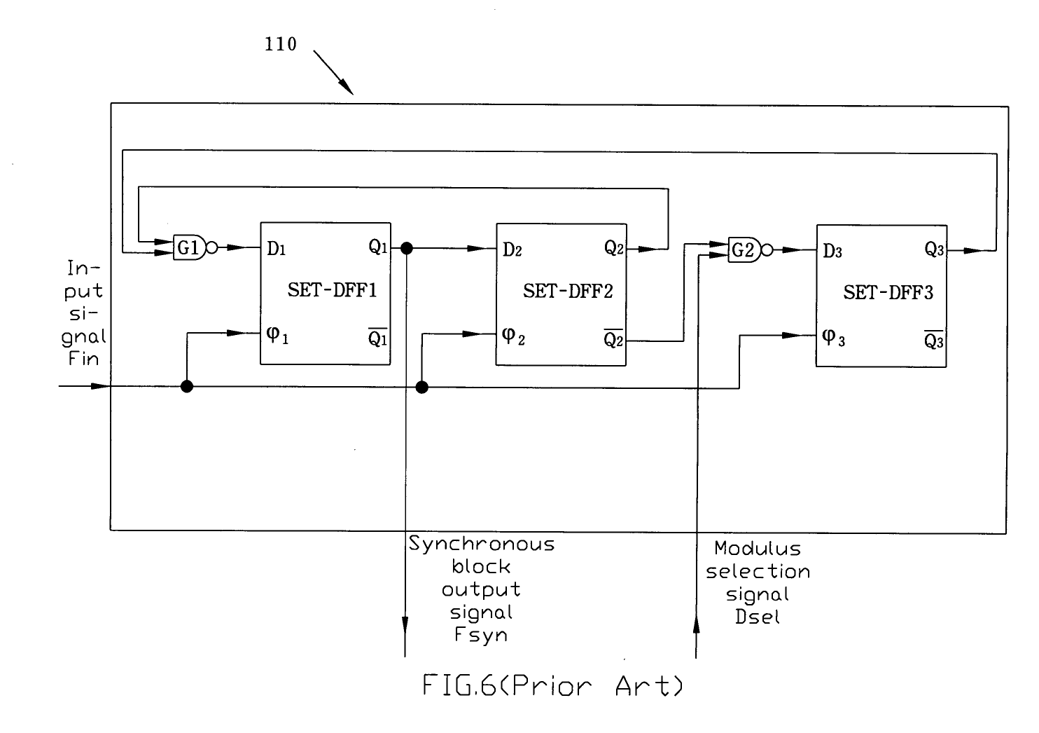

FIG. 6 is a circuit structure of a synchronous block of a prior art of a single edge triggered dual-modulus prescaler;

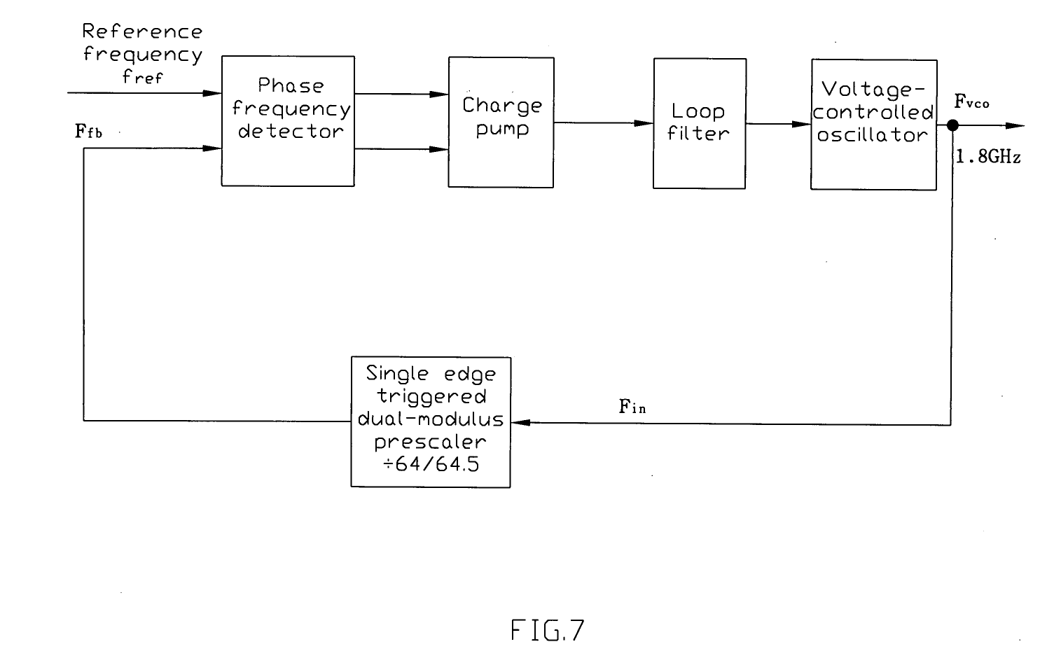

FIG. 7 is a block diagram of a frequency synthesizer based on the invention;

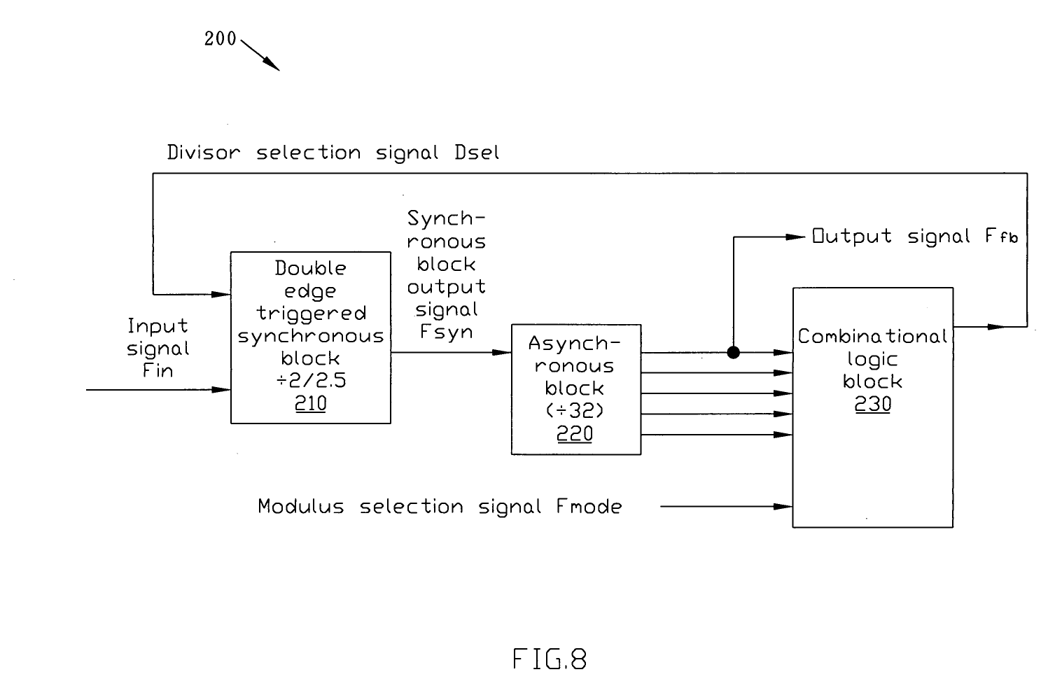

FIG. 8 is a block diagram of a double edge triggered dual-modulus prescaler of a preferred embodiment of the invention;

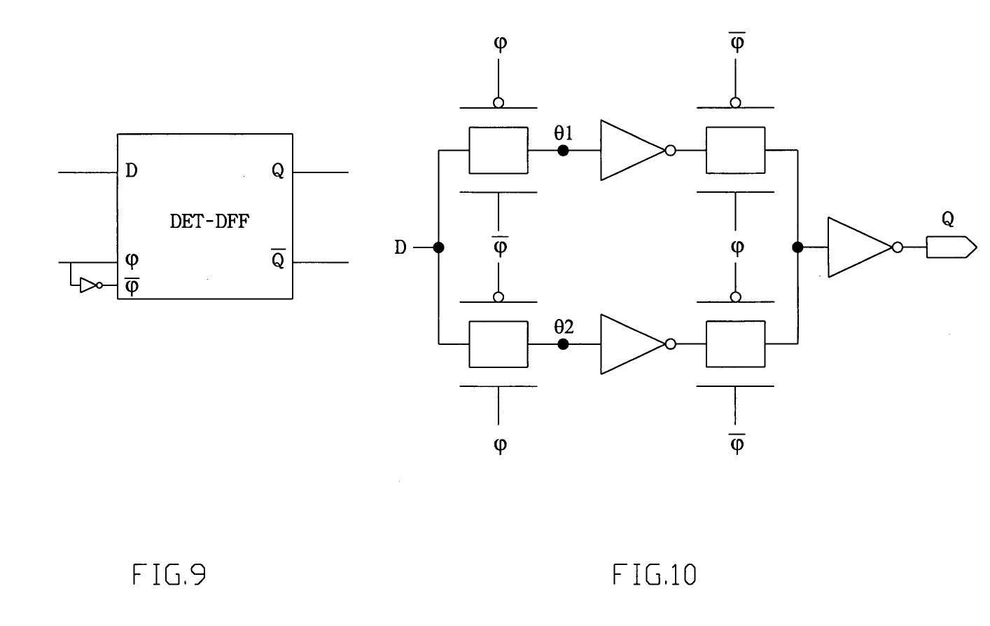

FIG. 9 is a diagram of a double edge triggered D-flip-flop;

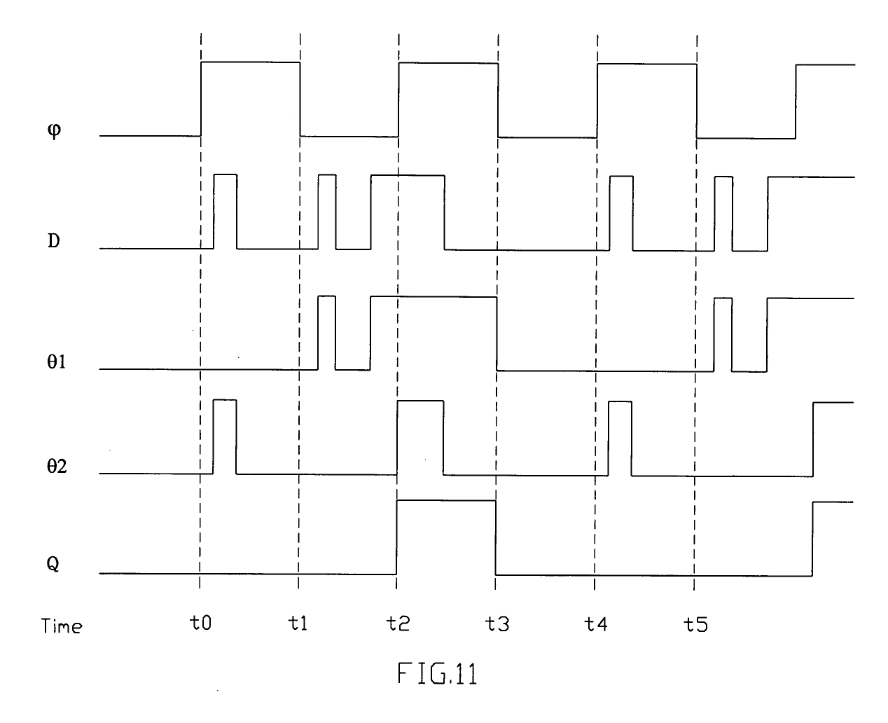

FIG. 10 is a practical circuit diagram of a double edge triggered D-flip-flop;

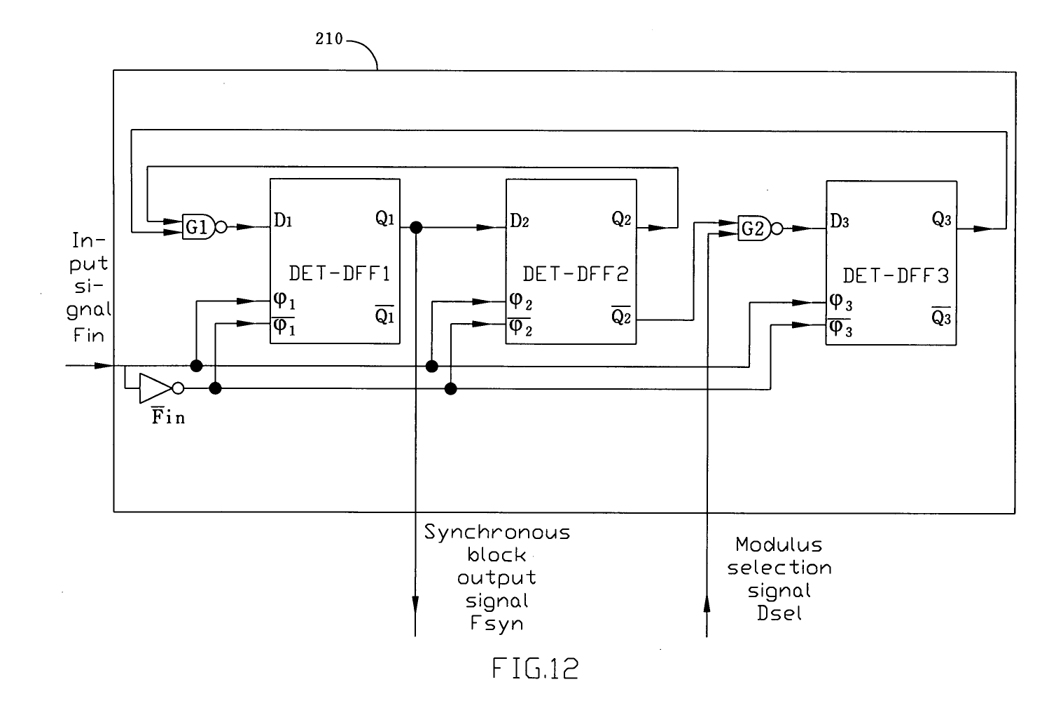

FIG. 11 is a timing diagram of a signal of a double edge triggered D-flip-flop;

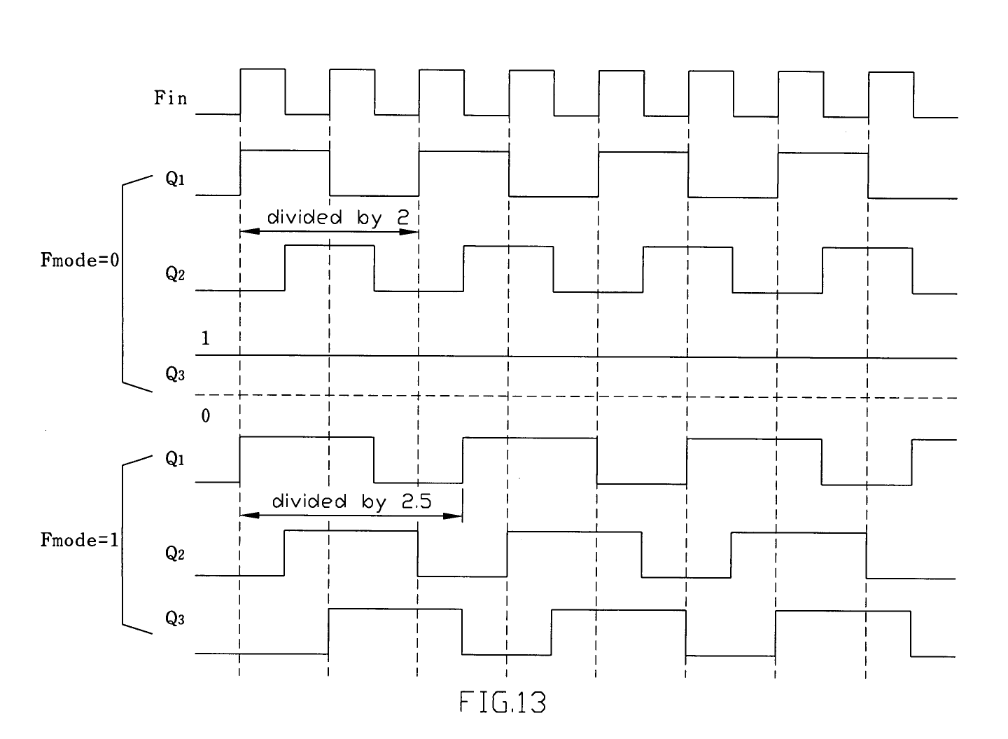

FIG. 12 is a circuit diagram of a synchronous block of a double edge triggered dual-modulus prescaler of an embodiment of the invention;

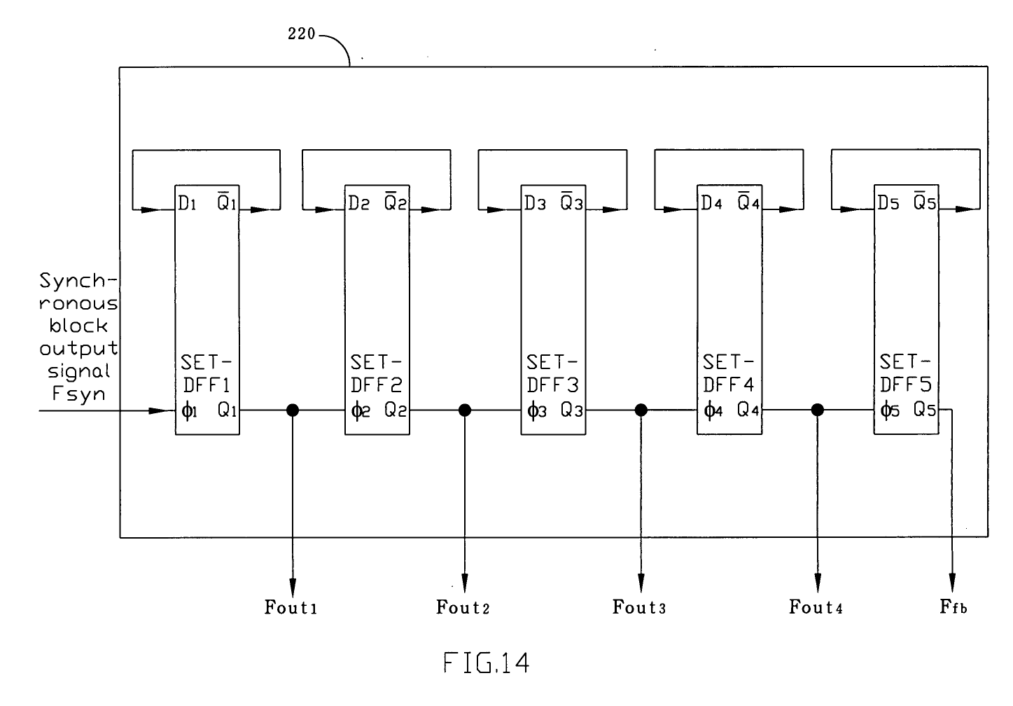

FIG. 13 is a timing diagram of a signal of a double edge triggered synchronous block (2/2.5);

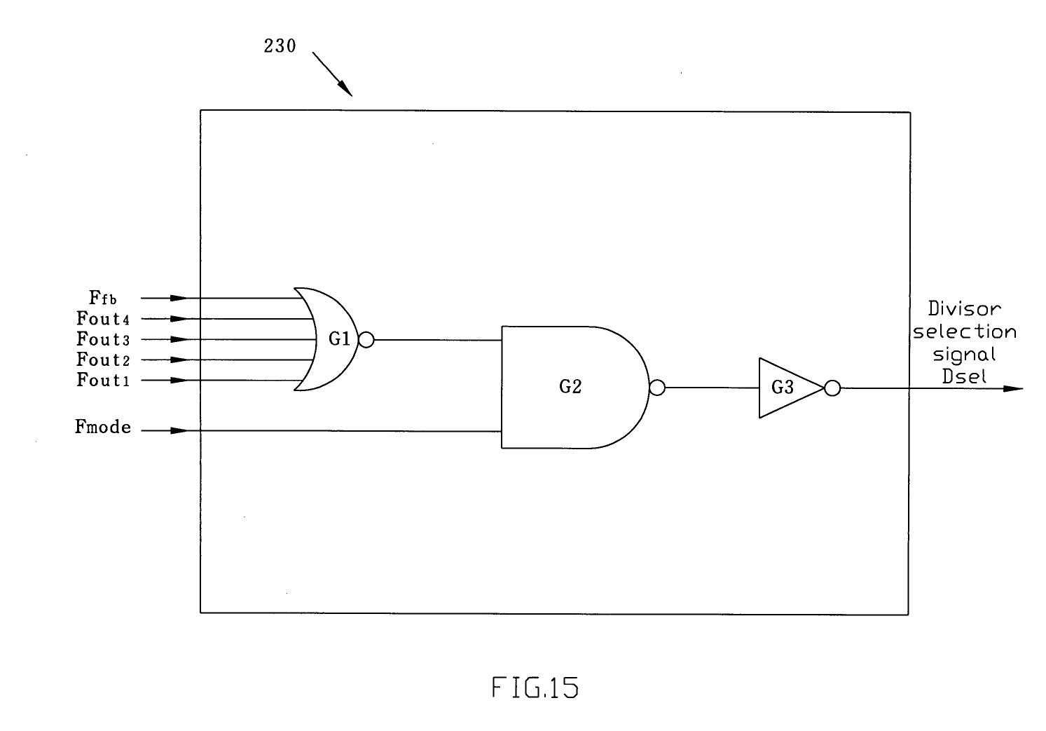

FIG. 14 is a circuit diagram of an asynchronous block of a double edge triggered dual-modulus prescaler of an embodiment of the invention;

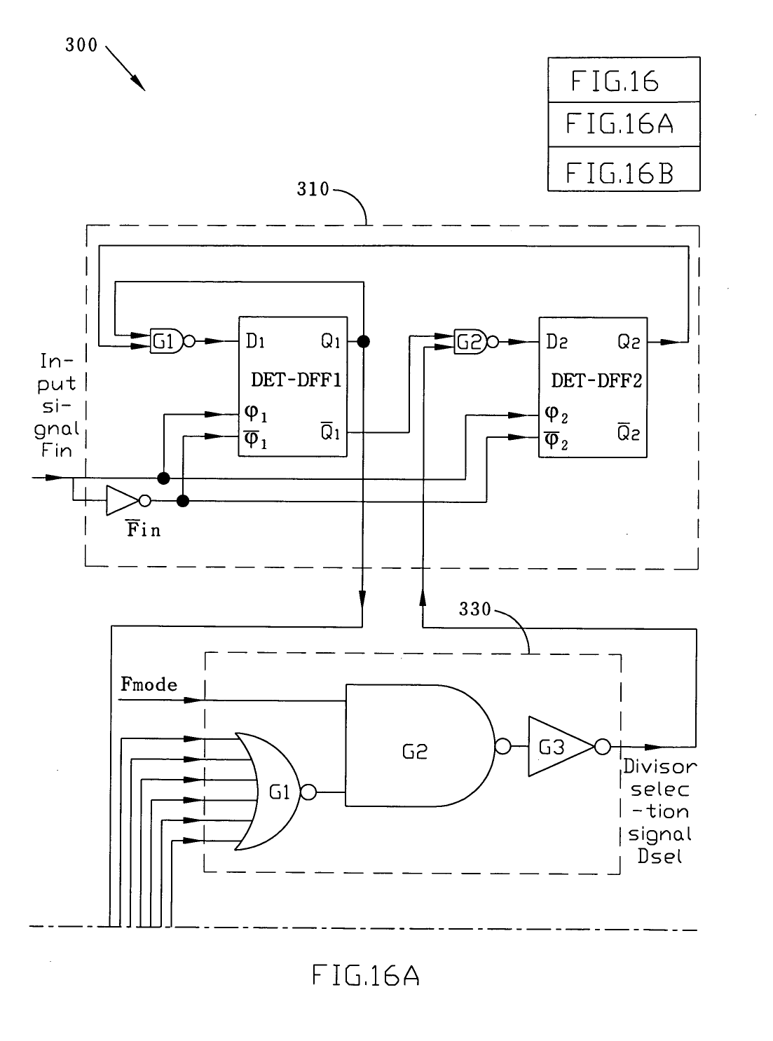

FIG. 15 is a circuit diagram of a combinational logic block of a double edge triggered dual-modulus prescaler of an embodiment of the invention;

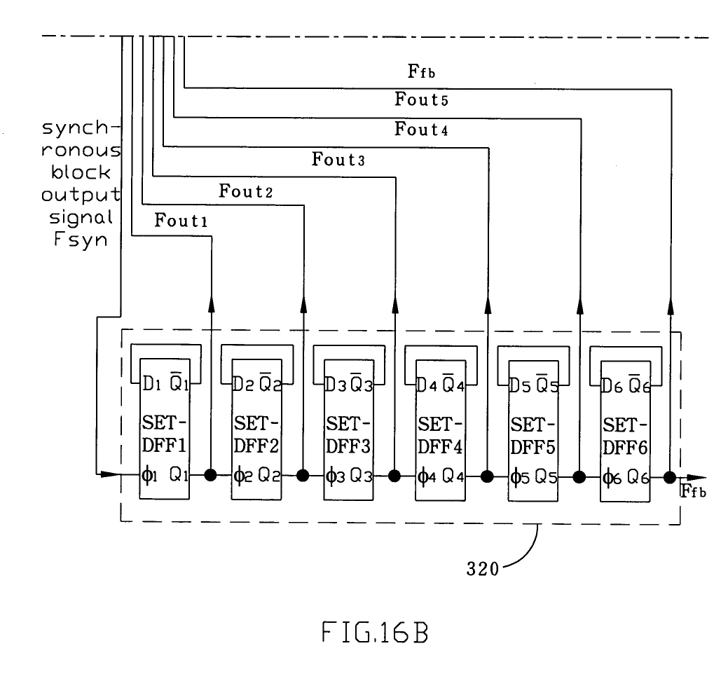

FIG. 16 is a circuit diagram of a double edge triggered dual-modulus prescaler of an embodiment of the invention;

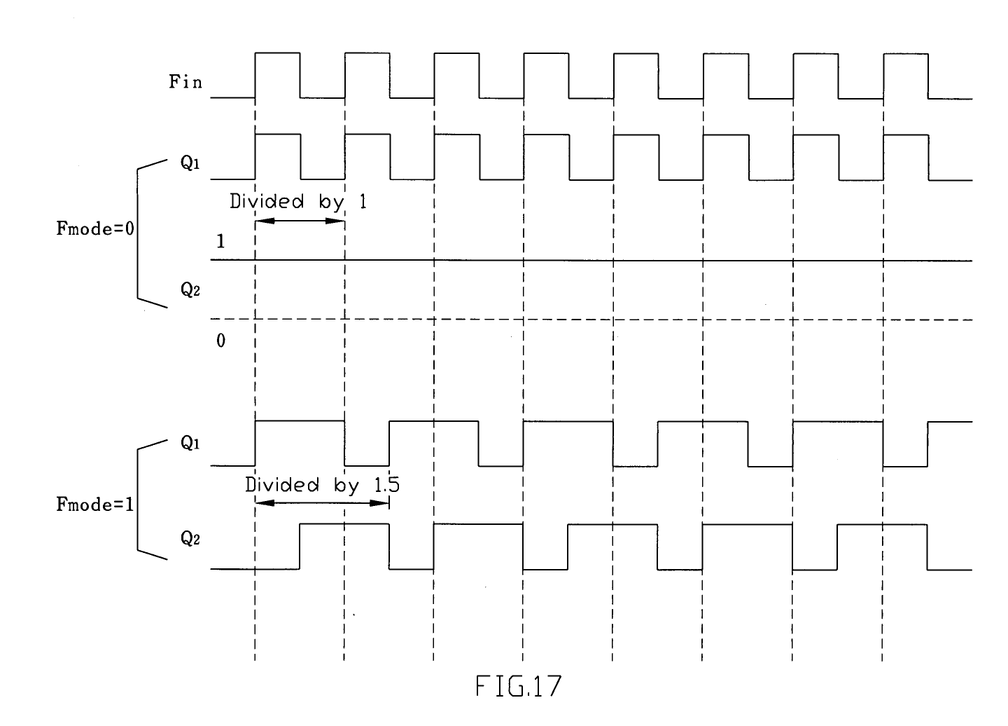

FIG. 17 is a timing diagram of a signal of a double edge triggered synchronous block (1/1.5);

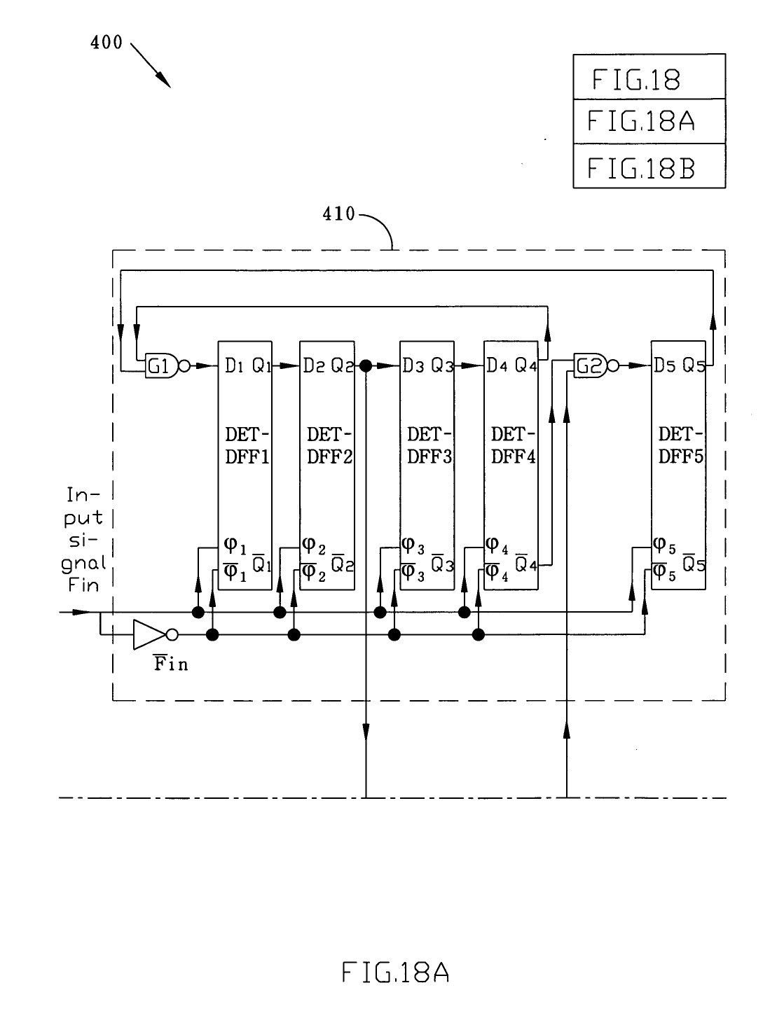

FIG. 18 is another circuit diagram of a double edge triggered dual-modulus prescaler of an embodiment of the invention;

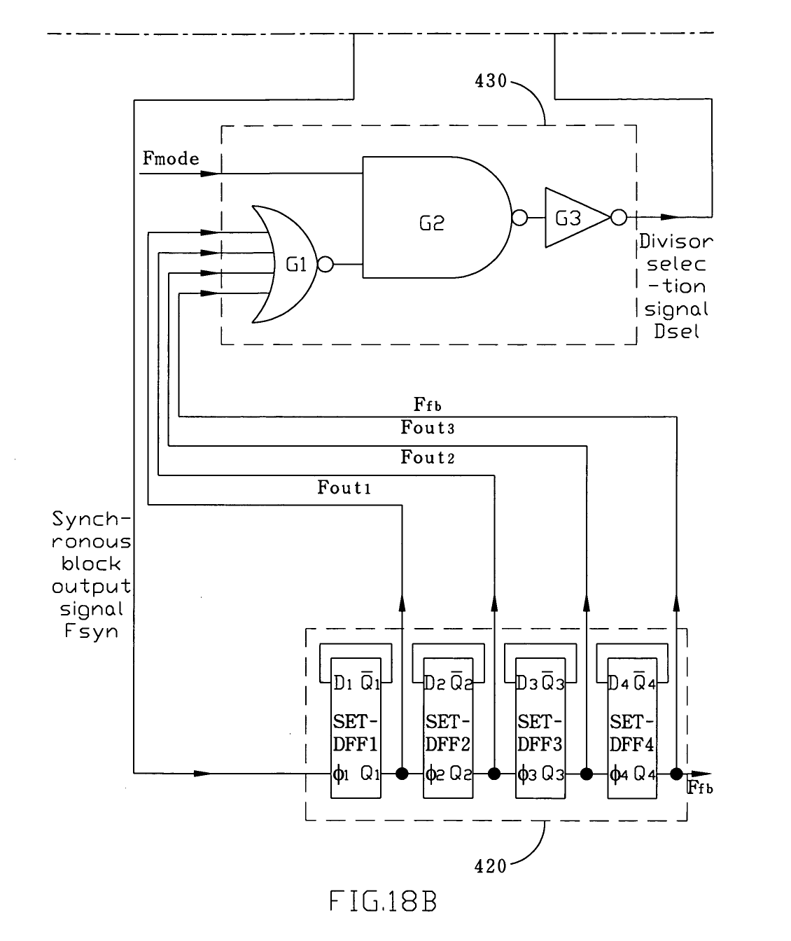

FIG. 19 is a timing diagram of a signal of a double edge triggered synchronous block (4/4.5);

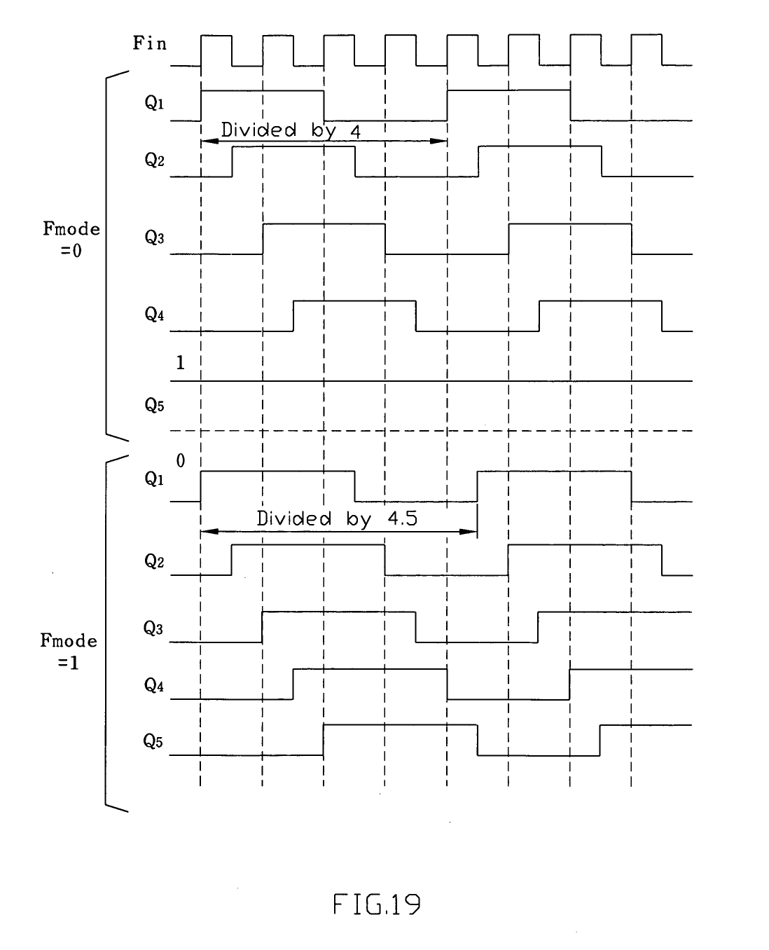

FIG. 20 is a comparison table of the prior art and the invention.

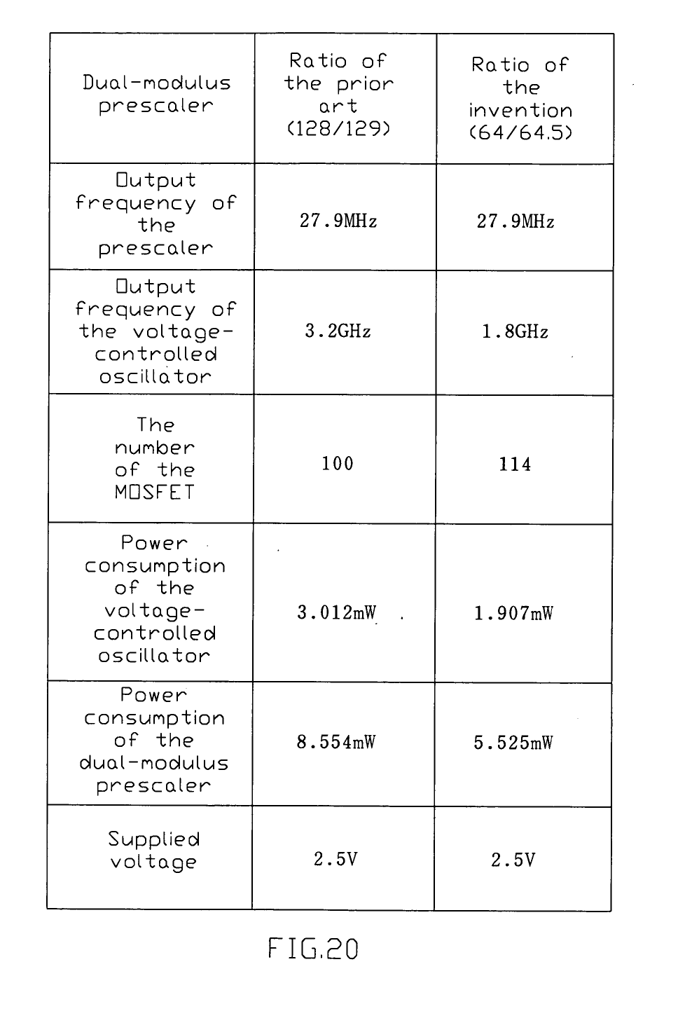

1. A structure of a double edge triggered dual-modulus prescaler, comprising:
a double edge triggered synchronous block with one end coupled with an input signal and a divisor selection signal and another end outputting a synchronous block signal;
an asynchronous block with one end coupled with another end of said double edge triggered synchronous block to receive a synchronous block output signal and another end outputting a plurality of output signals produced, one of said plurality of signals being an output of said double edge triggered dual-modulus prescaler; and
a combinational logic block with one end coupled with another end of said double edge triggered asynchronous block to receive said plurality of output signals and another end outputting said divisor selection signal, said divisor selection signal being fed back to said double edge triggered synchronous block in the meantime.

2. The structure of the double edge triggered dual-modulus prescaler as recited in claim 1, wherein said double edge triggered synchronous block comprises a plurality of double edge triggered D-flip-flops.

3. The structure of the double edge triggered dual-modulus prescaler as recited in claim 2, wherein the output of said double edge triggered synchronous block is an integer or noninteger

4. The structure of the double edge triggered dual-modulus prescaler as recited in claim 2, wherein said double edge triggered D-flip-flop comprises two single edge triggered D-flip-flops in parallel.

5. The structure of the double edge triggered dual-modulus prescaler as recited in claim 1, wherein said double edge triggered asynchronous block comprises a plurality of single edge triggered D-flip-flops.

6. The structure of the double edge triggered dual-modulus prescaler as recited in claim 1, wherein said combinational logic block is further coupled with a modulus selection signal to select one of the divisor selection signals as output of said combinational logic block.

7. The double edge triggered dual-modulus prescaler as recited in claim 6, wherein when the number of said single edge triggered D-flip-flops is a plurality, the frequency of the output signal of said double edge triggered dual-modulus prescaler is the frequency of said input signal divided by an integer or noninteger.

8. A double edge triggered dual-modulus prescaler, comprising:
a double edge triggered synchronous block with a function of division by 2/2.5, one end of which being coupled with an input signal and a divisor selection signal, and another end outputting a synchronous block output signal;
an asynchronous block with one end coupled with another end of said double edge triggered synchronous block to receive a synchronous block output signal and another end outputting a plurality of output signals produced, one of said plurality of signals being an output of said double edge triggered dual-modulus prescaler; and
a combinational logic block, one end of which being coupled with another end of said asynchronous block to receive said plurality of output signals and a modulus selection signal, and another end outputting said divisor selection signal, said divisor selection signal being fed back to said double edge triggered synchronous block in the meantime.

9. The double edge triggered dual-modulus prescaler as recited in claim 6, wherein said double edge triggered synchronous block with a function of division by 2/2.5 comprises 3 double edge triggered D-flip-flops.

10. The double edge triggered dual-modulus prescaler as recited in claim 7, wherein said double edge triggered D-flip-flop comprises 2 single edge triggered D-flip-flops in parallel.

11. The double edge triggered dual-modulus prescaler as recited in claim 6, wherein said asynchronous block comprises a plurality of single edge triggered D-flip-flops.

12. The double edge triggered dual-modulus prescaler as recited in claim 6 or 9, wherein when the number of said single edge triggered D-flip-flops is 5, the frequency of the output signal of said double edge triggered dual-modulus prescaler is the frequency of said input signal divided by 64 or 64.5 (64/64.5).

13. The double edge triggered dual-modulus prescaler as recited in claim 6, wherein when said modulus selection signal is “0”, the frequency of the output of said synchronous block is the frequency of said input signal divided by 2.

14. The double edge triggered dual-modulus prescaler as recited in claim 6, wherein when said modulus selection signal is “1”, the frequency of the output of said synchronous block is the frequency of said input signal divided by 2.5.

15. A double edge triggered dual-modulus prescaler, comprising:
a double edge triggered synchronous block with a function of division by 4/4.5, one end of which being coupled with an input signal and a divisor selection signal, and another end outputting a synchronous block output signal;
an asynchronous block with one end coupled with another end of said double edge triggered synchronous block to receive a synchronous block output signal and another end outputting a plurality of output signals produced, one of said plurality of signals being an output of said double edge triggered dual-modulus prescaler; and
a combinational logic block, one end of which being coupled with another end of said asynchronous block to receive said plurality of output signals and a modulus selection signal, and another end outputting said divisor selection signal, said divisor selection signal being fed back to said double edge triggered synchronous block in the meantime.

16. The double edge triggered dual-modulus prescaler as recited in claim 13, wherein the double edge triggered synchronous block with a function of division by 4/4.5 comprises 5 double edge triggered D-flip-flops.

17. The double edge triggered dual-modulus prescaler as recited in claim 14, wherein the double edge triggered D-flip-flop comprises 2 single edge triggered D-flip-flops in parallel.

18. The double edge triggered dual-modulus prescaler as recited in claim 13, wherein the asynchronous block comprises a plurality of single edge triggered D-flip-flops.

19. The double edge triggered dual-modulus prescaler as recited in claim 13 or 16, when the number of the single edge triggered D-flip-flops is 4, the frequency of the output signal of the double edge triggered dual-modulus prescaler is the frequency of the input signal divided by 64 or 64.5 (64/64.5)

20. The double edge triggered dual-modulus prescaler as recited in claim 13, when the modulus selection signal is “0”, the frequency of the output of the synchronous block is the frequency of the input signal divided by 4.

21. The double edge triggered dual-modulus prescaler as recited in claim 13, when the modulus selection signal is “1”, the frequency of the output of the synchronous block is the frequency of the input signal divided by 4.5.

22. A double edge triggered dual-modulus prescaler, comprising:
a double edge triggered synchronous block with a function of division by 1/1.5, one end of which being coupled with an input signal and a divisor selection signal, and another end outputting a synchronous block output signal;
an asynchronous block with one end coupled with another end of said double edge triggered synchronous block to receive a synchronous block output signal and another end outputting a plurality of output signals produced, one of said plurality of signals being an output of said double edge triggered dual-modulus prescaler; and
a combinational logic block, one end of which being coupled with another end of said asynchronous block to receive said plurality of output signals and a modulus selection signal, and another end outputting said divisor selection signal, said divisor selection signal being fed back to said double edge triggered synchronous block in the meantime.

23. The double edge triggered dual-modulus prescaler as recited in claim 20, wherein said double edge triggered synchronous block with a function of division by 1/1.5 comprises 2 double edge triggered D-flip-flops.

24. The double edge triggered dual-modulus prescaler as recited in claim 21, wherein said double edge triggered D-flip-flop comprises 2 single edge triggered D-flip-flops in parallel.

25. The double edge triggered dual-modulus prescaler as recited in claim 20, wherein said asynchronous block comprises a plurality of single edge triggered D-flip-flops.

26. The double edge triggered dual-modulus prescaler as recited in claim 20 or 23, wherein when the number of said single edge triggered D-flip-flops is 6, the frequency of the output signal of said double edge triggered dual-modulus prescaler is the frequency of said input signal divided by 64 or 64.5 (64/64.5).

27. The double edge triggered dual-modulus prescaler as recited in claim 20, wherein when said modulus selection signal is “0”, the frequency of the output of said synchronous block is the frequency of said input signal divided by 1.

28. The double edge triggered dual-modulus prescaler as recited in claim 20, wherein when said modulus selection signal is “1”, the frequency of the output of said synchronous block is the frequency of said input signal divided by 1.5.

29. A structure of a frequency synthesizer with a double edge triggered dual-modulus prescaler, comprising:
a double edge triggered synchronous block with one end coupled with an input signal and a divisor selection signal and another end outputting a synchronous block signal;
an asynchronous block with one end coupled with another end of said double edge triggered synchronous block to receive a synchronous block output signal and another end outputting a plurality of output signals produced, one of said plurality of signals being an output of said double edge triggered dual-modulus prescaler;
a combinational logic block with one end coupled with another end of said double edge triggered asynchronous block to receive said plurality of output signals and another end outputting said divisor selection signal, said divisor selection signal being fed back to said double edge triggered synchronous block in the meantime; and
an apparatus to synthesize frequency used to receive the output signal of said dual-modulus prescaler and a reference frequency.

30. The structure of the frequency synthesizer as recited in claim 29, wherein said double edge triggered synchronous block comprises a plurality of double edge triggered D-flip-flops.

31. The structure of the frequency synthesizer as recited in claim 29, wherein said double edge triggered D-flip-flop comprises two single edge triggered D-flip-flops in parallel.

32. The structure of the frequency synthesizer as recited in claim 29, wherein said double edge triggered asynchronous block comprises a plurality of single edge triggered D-flip-flops.

33. The structure of the frequency synthesizer as recited in claim 29, wherein said combinational logic block is further coupled with a modulus selection signal to select one of said divisor selection signals as output of said combinational logic block.

34. A structure of Phase-locked Loop (PLL) with a double edge triggered dual-modulus prescaler, comprising:
a double edge triggered synchronous block with one end coupled with an input signal and a divisor selection signal and another end outputting a synchronous block signal;
an asynchronous block with one end coupled with another end of said double edge triggered synchronous block to receive a synchronous block output signal and another end outputting an signals produced;
a combinational logic block with one end coupled with another end of said double edge triggered asynchronous block to receive said plurality of output signals and another end outputting said divisor selection signal, said divisor selection signal being fed back to said double edge triggered synchronous block in the meantime; and
an apparatus to synthesize frequency used to receive the output signal of said PLL and a reference frequency.

35. The structure of the PLL as recited in claim 34, wherein said double edge triggered synchronous block comprises a plurality of double edge triggered D-flip-flops.

36. The structure of the PLL as recited in claim 34, wherein said double edge triggered D-flip-flop comprises two single edge triggered D-flip-flops in parallel.

37. The structure of the PLL as recited in claim 34, wherein said double edge triggered asynchronous block comprises a plurality of single edge triggered D-flip-flops.

38. The structure of the PLL as recited in claim 34, wherein said combinational logic block is further coupled with a modulus selection signal to select one of said divisor selection signals as output of said combinational logic block.
